(19) United States
(12) Patent Application Publication
(10) Pub. No.: US 2025/0022806 A1
(43) Pub. Date: Jan. 16, 2025

(54) SEMICONDUCTOR PACKAGE

(71) Applicant: Samsung Electronics Co., Ltd., Suwon-si (KR)

(72) Inventor: Hong Jin KIM, Suwon-si (KR)

(21) Appl. No.: 18/757,570

(22) Filed: Jun. 28, 2024

(30) Foreign Application Priority Data
Jul. 11, 2023 (KR) 10-2023-0090103

(51) Int. Cl. H01L 23/538; H01L 23/00; H01L 23/31; H01L 23/498; H01L 25/065; H10B 80/00

(52) U.S. Cl. CPC H01L 23/5386; H01L 23/5383; H01L 24/16; H01L 24/48; H01L 25/0652; H01L 23/3107; H01L 23/49816; H01L 24/32; H01L 24/73; H01L 2224/16227; H01L 2224/32225; H01L 2224/48227; H01L 2224/73265; H10B 80/00

(57) ABSTRACT

A semiconductor package includes a package substrate including a wiring structure, a plurality of external connecting terminals below the package substrate, a first semiconductor chip flip-chip bonded on and above the package substrate, a second semiconductor chip above the package substrate and horizontally spaced apart from the first semiconductor chip, and wire-bonded on the package substrate, a first power/ground pad on an upper face of the second semiconductor chip, an option pad on the package substrate and connected to the first power/ground pad by a wire, an option bump below the first semiconductor chip and connected to the option pad through the wiring structure, and a connecting bump below the first semiconductor chip and connected to a first external connecting terminal of the plurality of external connecting terminals, wherein the option bump is not electrically connected to any external connecting terminal of the plurality of external connecting terminals through only the wiring structure.

### CROSS-REFERENCE TO RELATED APPLICATION

This application claims priority under 35 U.S.C. 119 to Korean Patent Application No. 10-2023-0090103 filed on Jul. 11, 2023, in the Korean Intellectual Property Office, the contents of which in its entirety are herein incorporated by reference.

### BACKGROUND

### 1. Field of the Invention

The present invention relates to a semiconductor package and a method for fabricating the same.

### 2. Description of the Related Art

In recent years, with the tendency of reduction in size and weight of electronic components, there has been a demand for reduction in size of semiconductor packages to be mounted thereon. While an area of the package is limited, the size and number of semiconductor chips that fit inside the package are increasing. Therefore, it is important to efficiently place the semiconductor chips within the limited area of the package.

A semiconductor package using a flip-chip bonding type has an advantage that improved electrical characteristics and a relatively low package height may be obtained compared to the conventional wire bonding.

### SUMMARY

Aspects of the present invention provide a semiconductor package having improved product reliability.

Aspects of the present invention also provide a method for fabricating the semiconductor package having improved product reliability.

According to some aspects of the present inventive concept, a semiconductor package includes a package substrate including a wiring structure, a plurality of external connecting terminals below the package substrate, a first semiconductor chip flip-chip bonded on and above the package substrate, a second semiconductor chip above the package substrate and horizontally spaced apart from the first semiconductor chip, and wire-bonded on the package substrate, a first power/ground pad on an upper face of the second semiconductor chip, an option pad on the package substrate and connected to the first power/ground pad by a wire, an option bump below the first semiconductor chip and connected to the option pad through the wiring structure, and a connecting bump below the first semiconductor chip and connected to a first external connecting terminal of the plurality of external connecting terminals, wherein the option bump is not electrically connected to any external connecting terminal of the plurality of external connecting terminals through only the wiring structure.

According to some aspects of the present inventive concept, a semiconductor package includes a package substrate, a wiring structure in the package substrate that includes all wiring components that connect between a top of the package substrate and a bottom of the package substrate, a plurality of external connecting terminals placed below the package substrate, a first semiconductor chip flip-chip bonded on and above the package substrate, a second semiconductor chip above the substrate and horizontally spaced apart from the first semiconductor chip, and wire-bonded on the package substrate, a first pad on an upper face of the second semiconductor chip, a second pad on the package substrate, and connected to the first pad by a wire, a first connecting pad spaced apart from the second pad on the package substrate, and connected to the first pad by a wire, an first bump below the first semiconductor chip on the package substrate, and electrically connected to and contacting the second pad, and a second bump spaced apart from the first bump below the first semiconductor chip, and electrically connected to a first external connecting terminal of the plurality of external connecting terminals directly through the wiring structure. The first bump is not electrically connected to any external connecting terminal of the plurality of external connecting terminals directly through the wiring structure, and the first connecting pad is electrically connected to a second external connecting terminal.

According to some aspects of the present inventive concept, a semiconductor package includes a package substrate including a wiring structure, an external connecting terminal placed below the package substrate, a first semiconductor chip on and above the package substrate, a second semiconductor chip stack spaced apart from the first semiconductor chip on the package substrate and above the package substrate, and including a plurality of stacked memory chips, a first power/ground pad on an upper face of the second semiconductor chip stack, a signal pad on an upper face of the second semiconductor chip stack, and spaced apart from the first power/ground pad, a second power/ground pad on the upper face of the second semiconductor chip stack, and spaced apart from the first power/ground pad and the signal pad, an option pad on the package substrate, and connected to the first power/ground pad by a wire, a first connecting pad spaced apart from the option pad on the package substrate, and connected to the first power/ground pad by the wire, a second connecting pad spaced from the option pad and the first connecting pad on the package substrate, and connected to the second power/ground pad, a third connecting pad spaced apart from the option pad, the first connecting pad, and the second connecting pad on the package substrate, and connected to the signal pad, an option bump below the first semiconductor chip on the package substrate, and electrically connected to the option pad through the wiring structure, a connecting bump spaced apart from the option bump below the first semiconductor chip, and electrically connected to the external connecting terminal and a molding film which covers the first semiconductor chip and the second semiconductor chip stack on the package substrate, wherein the first semiconductor chip includes a controller that controls the plurality of stacked memory chips, the option bump is not electrically connected to the external connecting terminal directly through the wiring structure, the option pad is not electrically connected to the external connecting terminal directly through the wiring structure, the first connecting pad, the second connecting pad, and the third connecting pad are electrically connected to the external connecting terminal, and the second connecting pad and the third connecting pad are not electrically connected to the option bump.

However, aspects of the present invention are not restricted to the one set forth herein. The above and other aspects of the present invention will become more apparent to one of ordinary skill in the art to which the present invention pertains by referencing the detailed description of the present invention given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view for explaining a semiconductor package according to some embodiments.

FIGS. 2 to 4 are cross-sectional views for explaining the semiconductor package according to some embodiments.

FIGS. 5 to 12 are cross-sectional views for explaining a semiconductor package according to some other embodiments.

### DETAILED DESCRIPTION OF THE EMBODIMENTS

Hereinafter, embodiments according to the technical idea of the present invention will be described referring to the accompanying drawings.

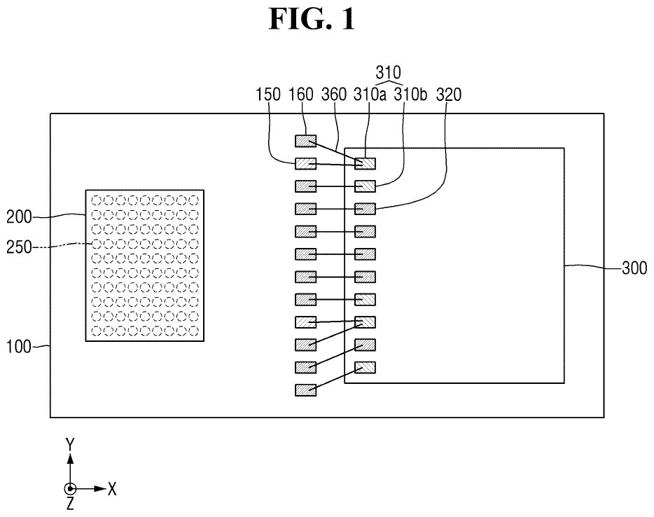

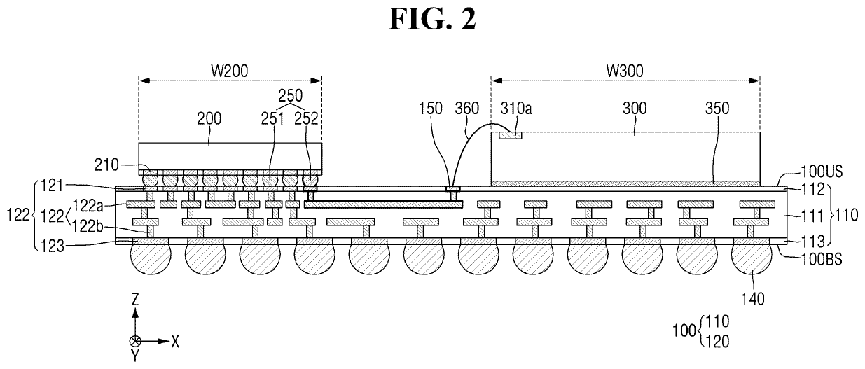

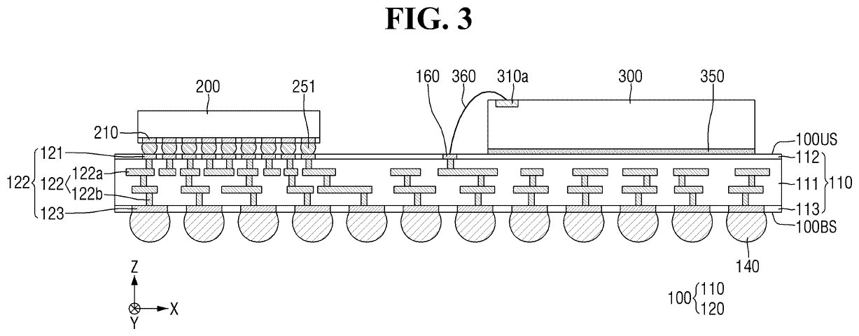

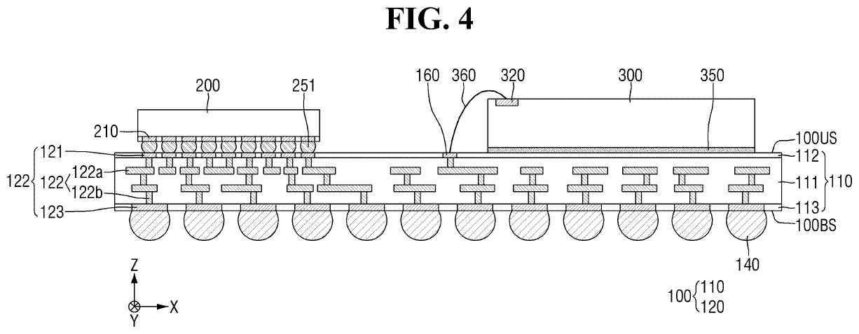

FIG. 1 is a plan view for explaining a semiconductor package according to some embodiments. FIGS. 2 to 4 are cross-sectional views for explaining the semiconductor package according to some embodiments.

Referring to FIGS. 1 to 4, a semiconductor package according to some embodiments may include a package substrate 100, a first semiconductor chip 200, a second semiconductor chip 300, one or more option bumps 252, and one or more option pads 150.

The package substrate 100 may be a wiring structure for package. For example, the package substrate 100 may be a printed circuit wiring structure (PCB), a ceramic wiring structure, or the like. Alternatively, the package substrate 100 may be a wiring structure for a wafer level package (WLP) fabricated at a wafer level. The package substrate 100 may include a lower face 100BS (e.g., lower or bottom surface) and an upper face 100US (e.g., upper or top surface) that are opposite to each other.

The package substrate 100 may extend in a first direction X and a second direction Y. The first direction X and the second direction Y may each be directions parallel to the upper face 100US of the package substrate, and may each be described as a horizontal direction. A third direction Z may be a direction that intersects each of the first direction X and the second direction Y and is perpendicular to the upper face 100US of the package substrate, and may be described as a vertical direction.

The package substrate 100 may include a first insulating layer 110 and a wiring structure 120. The first insulating layer 110 may include a first substrate 111, a first lower passivation film 113 and a first upper passivation film 112. The wiring structure 120 may include a lower substrate pad 123, a first wiring 122, and an upper substrate pad 121. Items described herein in the singular (e.g., pads, among other components) may be provided in plural, as can be seen, for example, from various of the figures.

The first substrate 111 may be, for example, a printed circuit board (PCB) or a ceramic substrate. However, the technical idea of the present invention is not limited thereto.

When the first substrate 111 is a printed circuit board, the first insulating layer 110 may be made up of at least one material selected from phenol resin, epoxy resin, and polyimide. The first insulating layer 110 may include or be formed of, for example, at least one material selected from FR-4, tetrafunctional epoxy, polyphenylene ether, epoxy/polyphenylene oxide, BT (bismaleimide triazine), thermount, cyanate ester, polyimide, and liquid crystal polymer. The surface of the first substrate 111 may be covered with a solder resist. For example, the first lower passivation film 113 and the first upper passivation film 112 formed on the surface of the first substrate 111 may be the solder resist. However, the technical idea of the present invention is not limited thereto.

Although first substrate 111 is shown to be a single layer, this is only for convenience of explanation. For example, the first substrate 111 may be made up of multiple layers to form the first wiring 122 of multiple layers (e.g., multiple sub-layers each formed of a wiring layer and an insulating layer may be consecutively formed).

The wiring structure 120 may be inside the first insulating layer 110. The wiring structure 120 may be made up of the first wiring 122 for electrically connecting the lower substrate pad 123 and the upper substrate pad 121. The first wiring 122 may include a plurality of wiring patterns 122a, which may be grouped into a plurality of wiring layers, and a plurality of vias 122b for forming wiring paths. The upper substrate pad 121, the first wiring 122, and the lower substrate pad 123 may each include or be formed of a conductive material. For example, the upper substrate pad 121, the first wiring 122 and the lower substrate pad 123 may each include or be formed of gold (Au), silver (Ag), copper (Cu), nickel (Ni) or aluminum (Al). In some embodiments, the upper substrate pads 121, the first wirings 122 and the lower substrate pads 123 are all formed of the same material or set of materials (e.g., one or more of gold (Au), silver (Ag), copper (Cu), nickel (Ni) or aluminum (Al)). The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

In some embodiments, an external connecting terminal 140 may be formed on the lower face 100BS of the package substrate 100. The external connecting terminal 140 may be attached to the lower substrate pad 123 (e.g., each external connection terminal 140 may be attached to a respective lower substrate pad 123). The external connecting terminal 140 may contact the lower substrate pad 123. The external connecting terminal 140 may be placed below the lower substrate pad 123. The external connecting terminal 140 may include or be a solder ball or a solder bump. The external connecting terminal 140 may have, for example, but is not limited to, a spherical shape or an oval shape. The number, intervals, placement, form, and the like of the external connecting terminals 140 are not limited to those shown in the drawings, and may, of course, vary depending on the design. The external connecting terminal 140 may include or be formed of, for example, but is not limited to, tin (Sn), indium (In), bismuth (Bi), antimony (Sb), copper (Cu), silver (Ag), zinc (Zn), lead (Pb) and combinations thereof.

The external connecting terminal 140 may electrically connect the wiring structure 120 to an external device, and may be described as a package terminal. Accordingly, the external connecting terminal 140 may provide the electrical signal to the wiring structure 120 or may provide the electrical signal provided from the wiring structure 120 to the external device.

For example, external connecting terminals 140 may provide respective electrical signals to the second semiconductor chip 300. The external connecting terminals 140 may provide a power signal and a ground signal intended for the second semiconductor chip 300 to the wiring structure 120. The external connecting terminals 140 may receive signals that are to be input to the second semiconductor chip 300. The external connecting terminals 140 may receive signals that are output from the second semiconductor chip 300.

An option pad 150 and a connecting pad 160 may be placed on the upper face 100US of the package substrate. The option pad 150 and the connecting pad 160 may be placed, for example, to be spaced apart in the second direction Y. A plurality of option pads 150 and a plurality of connection pads 160 maybe included, as shown but not labeled in FIG. 1. For example, a first option pad 150 is labeled in FIG. 1. A second option pad may be in the row of pads below the labeled option pad 150, for example, the fourth pad from the bottom. The remaining pads in the row may be connection pads 160.

The option pad 150 may be connected to the option bump 252 through the wiring structure 120. The option pad 150 may provide the option bump 252 with power signal or ground signal provided to the power/ground pad 310 through one of the connecting pads 160. Each option bump 252 of the first semiconductor chip 200 may be connected to a control circuit in the first semiconductor chip 200 that determines how the first semiconductor chip 200 controls the second semiconductor chip 300. A plurality of option bumps 252 may be included so that more than one signal can be used to determine different ways in which the first semiconductor chip 200 can control the second semiconductor chip 300. Therefore, each option bump 252, or set of option bumps 252, is used to select from two or more options of how the first semiconductor chip 200 can control the second semiconductor chip 300. Additional details about the signals supplied to the option bumps 252 will be described further below.

A first connecting pad 160 (e.g., top pad 160 in FIG. 1) may be connected to the power/ground pad 310 and a second connecting pad 160 may be connected to the signal pad 320. The connecting pad 160 connected to the power/ground pad 310 may provide the power/ground pad 310 with the power signal or the ground signal received from the external connecting terminal 140. The connecting pad 160 connected to the signal pad 320 may transmit and receive a data signal to and from the signal pad 320. For example, the connecting pad 160 may provide a data input signal provided from the external connecting terminal 140 to the signal pad 320. As another example, the connecting pad 160 may provide the external connecting terminal 140 with the data output signal received from the signal pad 320. Accordingly, certain terminals and/or pads may be described as signal terminals and/or pads, power terminals and/or pads, or ground terminals and/or pads. Signal terminals or signal pads described as connected to a semiconductor chip are electrically connected to circuitry within the semiconductor chip designed to receive a signal and to process and/or store the signal. Ground terminals or ground pads described as connected to a semiconductor chip are electrically connected to circuitry within the semiconductor chip that serves to provide a ground connection to the semiconductor chip during operation. Power terminals or power pads described as connected to a semiconductor chip are electrically connected to circuitry within the semiconductor chip that serves to provide a power source voltage to the semiconductor chip during operation. A pad described as a power/ground pad is connected to receive either a power source voltage or a ground voltage to the semiconductor chip during operation.

The connecting pad 160 may be connected to the external connecting terminal 140 through the wiring structure 120. The connecting pad 160 may be connected to the connecting bump 251 through the wiring structure 120. For example, the connecting pad 160 connected to the connecting bump 251 may provide command/address signal of first semiconductor chip 200 to the signal pad 320 connected by a wire 360. The connecting pads 160 may not be connected to the option bumps directly through the substrate 100.

A first semiconductor chip 200 and a second semiconductor chip 300, which will be described below, may each include an integrated circuit. Each of the first semiconductor chip 200 and the second semiconductor chip 300 may include an active face on which the integrated circuit is formed, and an inactive face opposite to the active face. The active face may be called a front side surface, and the inactive face may be called a back side surface.

For example, a first lower pad 210 capable of applying a signal to the first semiconductor chip 200 may be placed on the active face of the first semiconductor chip 200. A power/ground pad 310 and a signal pad 320 capable of applying the signal to the second semiconductor chip 300 may be placed on the active face of the second semiconductor chip 300.

The first semiconductor chip 200 may be placed on the package substrate 100. The first semiconductor chip 200 may be placed on the upper face 100US of the package substrate. The first semiconductor chip 200 may be flip-chip bonded onto the package substrate 100. The first semiconductor chip 200 may be electrically connected to the package substrate 100 through the lower bumps 250.

The first semiconductor chip 200 may include first lower pads 210. The first lower pads 210 may be placed on the lower face of the first semiconductor chip 200.

The first semiconductor chip 200 may be a logic semiconductor chip. The logic semiconductor chip may be, for example, but is not limited to, an application processor (AP), such as a CPU (Central Processing Unit), a GPU (Graphic Processing Unit), a FPGA (Field-Programmable Gate Array), a digital signal processor, a cryptographic processor, a microprocessor, a microcontroller, and an ASIC (Application-Specific IC).

The first semiconductor chip 200 may be or may include a controller that controls the second semiconductor chip 300.

Lower bumps 250 may be placed on the first lower pads 210. The lower bumps 250 may be placed between the first lower pads 210 of the first semiconductor chip 200 and the upper substrate pad 121 of the package substrate 100. The lower bumps 250 may contact the first lower pads 210 of the first semiconductor chip 200 and the upper substrate pads 121 of the package substrate 100. The term “contact,” “contacting,” “contacts,” or “in contact with,” as used herein, refers to a direct connection (i.e., touching) unless the context clearly indicates otherwise.

The lower bumps 250 may electrically connect the first semiconductor chip 200 and the package substrate 100. The first semiconductor chip 200 may receive the electrical signal from the package substrate 100 through the lower bumps 250.

The lower bumps 250 may include a connecting bump 251 (e.g., a plurality of connecting bumps 251) and an option bump 252 (e.g., one or more option bumps 252). The connecting bumps 251 and the option bumps 252 may be placed to be spaced apart from each other. Each connecting bump 251 and option bump 252 may have the same size. However, embodiments are not limited thereto. For example, the connecting bumps 251 and the option bumps 252 may have different sizes.

The connecting bump 251 may be electrically connected to the external connecting terminal 140 through the wiring structure 120 of the package substrate 100. The connecting bump 251 may receive the input signal for the first semiconductor chip 200 from the outside through the external connecting terminal 140, and transmit the input signal to the first semiconductor chip 200. The connecting bump 251 may provide the output signal of the first semiconductor chip 200 to the outside through the external connecting terminal 140.

The option bump 252 may be connected to the option pad 150 through the wiring structure 120 of the package substrate 100. The option bump 252 may not be connected to the external connecting terminal 140 through only the wiring structure 120. The option bump 252 may be connected to a power/ground pad 310 (e.g., a pad that provides either a power signal such as positive voltage or a ground signal such as zero volts) of the second semiconductor chip 300 through the option pad 150. The option bump 252 may receive a power signal or a ground signal from the power/ground pad 310 of the second semiconductor chip 300. To explain another way, the wiring structure 120 in the insulating layer 110 may include all wiring components that connect between a top of the package substrate 100 (e.g., 100US) and a bottom of the package substrate 100 (e.g., 100BS). Some of the connection bumps (e.g., connecting bumps 251) may electrically connect to respective external connecting terminals 140 directly through the wiring structure 120 (e.g., without requiring passing through a wire 360 or a pad of the second semiconductor chip 300). Other of the connection bumps (e.g., option bump 252) may connect to an external connection terminal 140 through the wiring structure 120 in addition to through conductive lines outside of the wiring structure (e.g., such as a wire 360 or a pad of the second semiconductor chip 300). These connection bumps do not connect to any external connection terminals 140 directly through the wiring structure 120. When there is a need for the option for controlling the operation of the second semiconductor chip 300, the option can be controlled during the manufacturing process by connecting an option pad 150 on the substrate 100, which is connected to option bump 252 of the first semiconductor device 200 through the substrate 100, to either a ground pad or a power pad among power/ground pads 310 of the second semiconductor chip 300. For example, a first control option can be selected by connecting the option pad 150 to a power pad of the second semiconductor chip 300 (e.g., 310a) through wire bonding, and a second control option can be selected by instead connecting the option pad 150 to a ground pad of the second semiconductor chip 300 (e.g., 310b) through wire bonding. In FIG. 1, the example where the option pad 150 is wire bonded to the power/ground pad 310a is shown.

A second semiconductor chip 300 may be placed on the package substrate 100. The second semiconductor chip 300 may be spaced apart from the first semiconductor chip 200 in the first direction X. The second semiconductor chip 300 may be placed on the upper face 100US of the package substrate. The second semiconductor chip 300 may be wire-bonded on the package substrate 100. The second semiconductor chip 300 may be electrically connected to the package substrate 100 through the wire 360.

The second semiconductor chip 300 may be a semiconductor chip different from the first semiconductor chip 200. The second semiconductor chip 300 may be a memory semiconductor chip. The memory semiconductor chip may be, for example, a volatile memory such as a dynamic random access memory (DRAM) or a static random access memory (SRAM). Alternatively, the memory semiconductor chip included in the second semiconductor chip 300 may be a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

The second semiconductor chip 300 may include an adhesive layer 350. The adhesive layer 350 may be placed on the lower face of the second semiconductor chip 300. The adhesive layer 350 may cover the lower face of the second semiconductor chip 300. The adhesive layer 350 may be placed between the second semiconductor chip 300 and the package substrate 100. The adhesive layer 350 may include or be formed of a non-conductive film (NCF), a non-conductive paste (NCP), an insulating polymer or an epoxy resin. However, the technical idea of the present invention is not limited thereto.

The second semiconductor chip 300 may include a power/ground pad 310 and a signal pad 320. For example, the second semiconductor chip 300 may include a plurality of pads that received either power or a ground potential (e.g., power/ground pads 310) and a plurality of pads that receive signals (e.g., signal pads 320). The power/ground pads 310 and the signal pads 320 may be placed on the upper face of the second semiconductor chip 300. A power/ground pad 310 may be electrically connected to an option pad 150 and a connecting pad 160 of the package substrate 100 through wires 360. For example, according to one operational setting, the power/ground pad 310a may be electrically connected to an option pad 150 through a first wire 360 and to a first connecting pad 160 (e.g., the top pad in FIG. 1) through a second wire 360. In this example, the power/ground pad 310b may be electrically connected to a second connecting pad 160 (e.g., the third pad from the top in FIG. 1) through a third wire 360, and a signal pad 320 may be electrically connected to a third connecting pad 160 (e.g., the fourth pad from the top) through a fourth wire 360. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The power/ground pads 310 and the signal pads 320 may be placed on the upper face of the second semiconductor chip 300 to be spaced apart from each other. For example, the power/ground pads 310 and the signal pads 320 may be placed to be spaced apart from each other in the second direction Y.

The power/ground pads 310 may include a first power/ground pad 310a and a second power/ground pad 310b. For example, the first power/ground pad 310a may be connected to a first connecting pad 160 that receives one of power or a ground potential, and the second power/ground pad 310b may be connected to a second connecting pad 160 that receives the other of power or a ground potential. In one particular operational setting (e.g., a first option for the semiconductor package), the first power/ground pad 310a may be connected, through a first wire bonding, to the option pad 150, and through a second wire bonding, to the first connecting pad 160. Therefore, the first option pad 150 receives whatever voltage potential (e.g., either power or ground potential) is supplied to the first connecting pad 160. In this operational setting, the second power/ground pad 310b is connected to a second connecting pad 160, which receives whatever voltage potential (e.g., either power or ground potential) is supplied to the first connecting pad 160, and is not connected to the option pad 150.

In a different particular operational setting (e.g., a second option for the semiconductor package), the first power/ground pad 310a may not be connected to the option pad 150, and instead the second power/ground pad 310b is connected to the option pad 150. In this case, the second power/ground pad 310b is connected to the option pad 150, for example, through third wire bonding, and is connected as well to a second connecting pad 160 (e.g., third pad from the top in FIG. 1) through a fourth wire bonding. Therefore, the first option pad 150 receives whatever voltage potential (e.g., either power or ground potential) is supplied to the second connecting pad 160. In this operational setting, the first power/ground pad 310a is connected to the first connecting pad 160, which receives whatever voltage potential (e.g., either power or ground potential) is supplied to the first connecting pad 160, and is not connected to the option pad 150. In this manner, by wire bonding the option pad 150 to either a first power/ground pad 310a or a second power/ground pad 310b, a control option for controlling the second semiconductor chip 300 by the first semiconductor chip 200 may be selected. It should be noted that more than one option pad may be included on the substrate 100, as can be seen in FIG. 1 (e.g., the fourth pad from the bottom on the substrate 100 is an option pad). In this case, more than two options for operational control of the second semiconductor chip 300 maybe selected from. For example, because each option pad 150 can be connected through wire bonding to either a power pad or a ground pad, when two option pads 150 are connected to two option bumps 252 on the first semiconductor chip 200, up to four options for operational control can be selected from.

As mentioned above, a power/ground pad 310 may receive a power signal or a ground signal. As used in the claims herein, when the term “power/ground pad” or when any other pad is described in the singular, only a single pad is being described. On the contrary, in the claims, when “pads” or “at least one pad” or “one or more pads” is described, the mentioned component is or may be provided in plural.

The first power/ground pad 310a may be connected to the external connecting terminal 140 through a first connecting pad 160. Specifically, the first power/ground pad 310a may be electrically connected to the external connecting terminal 140 through the first connecting pad 160 and the wiring structure 120. The second semiconductor chip 300 may receive a power signal or a ground signal through the first connecting pad 160 and the external connecting terminal 140 connected to the first power/ground pad 310a.

The first connecting pad 160 connected to the first power/ground pad 310a may not be electrically connected to the first semiconductor chip 200 only through the wiring structure 120. For example, the first connecting pad 160 connected to the first power/ground pad 310a may not be electrically connected through only the wiring structure 120 to the connecting bump 251 and the option bump 252.

The first power/ground pad 310a may be connected to the option bump 252 of the second semiconductor chip 200 through the option pad 150. Specifically, the option pad 150 may be electrically connected only to the option bump 252 through the wiring structure 120. Therefore, the option pad 150 may not be connected to the external connecting terminal 140 through the wiring structure 120.

The option bump 252 may be electrically connected to first power/ground pad 310a through the option pad 150. The option bump 252 may receive the power signal or the ground signal, which is provided to the first power/ground pad 310a through the first connecting pad 160 and the external connecting terminal 140, from the first power/ground pad 310a through the option pad 150. When the first power/ground pad 310a is connected via wire bonding to the option pad 150, the first semiconductor chip 200 may utilize the power signal or ground signal provided from the first power/ground pad 310a through the option pad 150, to control the operation of the second semiconductor chip 300.

The second power/ground pad 310b may receive the power signal or ground signal of the second semiconductor chip 300 through the second connecting pad 160 and the external connecting terminal 140. For example, in one embodiment, if the first connecting pad 160 receives a power signal, the second connecting pad 160 receives a ground signal, and vice versa. When the first power/ground pad 310a is connected via wire bonding to the option pad 150, the second power/ground pad 310b is not electrically connected to the option pad 150, and so the power signal or ground signal provided through the external connecting terminal 140 to the second connecting pad 160 is not be provided to the corresponding option bump 252 of the first semiconductor chip 200.

The signal pad 320 may be connected to the external connecting terminal 140 through a different connecting pad 160. The second semiconductor chip 300 may transmit and receive input/output signal to and from an external connecting terminal 140 through a signal pad 320 and a connecting pad 160 that are connected to each other. For example, the second semiconductor chip 300 may receive the input signal from an external connecting terminal 140 through a signal pad 320 and a corresponding connecting pad 160. As another example, the second semiconductor chip 300 may output the data signal to an external connecting terminal 140 through a signal pad 320 and a corresponding connecting pad 160.

The signal pad 320 may be connected to the first semiconductor chip 200 through the connecting pad 160. For example, the second semiconductor chip 300 may receive the command/address signal from the first semiconductor chip 200 through the signal pad 320 and the connecting pad 160 that are connected to each other. As another example, the second semiconductor chip 300 may output the data signal to the first semiconductor chip 200 through the signal pad 320 and the connecting pad 160.

The signal pad 320 may not be electrically connected to the option pad 150. The signal pad 320 may not be connected to the option pad 150 through the wire 360.

The second semiconductor chip 300 may be electrically connected to the package substrate 100 through the power/ground pad 310 and the signal pad 320. The second semiconductor chip 300 may be electrically connected to the option pad 150 and the connecting pad 160 of the package substrate 100 through the power/ground pad 310. The second semiconductor chip 300 may be electrically connected to the package substrate 100 through the signal pad 320.

The first semiconductor chip 200 may have a first width W200. The second semiconductor chip 300 may have a second width W300. The second width W300 of the second semiconductor chip 300 may be greater than the first width W200 of the first semiconductor chip 200.

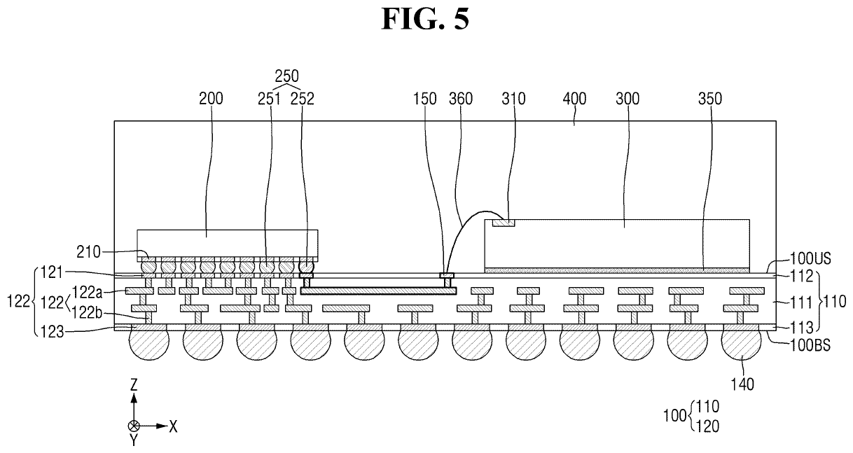

FIGS. 5 to 12 are cross-sectional views for explaining a semiconductor package according to some other embodiments. For convenience of explanation, the explanation will focus on points that are different from those explained referring to FIGS. 1 to 4.

Referring to FIG. 5, the semiconductor package according to some embodiments may include a molding film 400. The molding film 400 may be placed on the package substrate 100. The molding film 400 may cover the upper face 100US of the package substrate.

The molding film 400 may cover the first semiconductor chip 200 and the second semiconductor chip 300 on the package substrate 100. The molding film 400 may cover the upper face of the first semiconductor chip 200 and the upper face of the second semiconductor chip 300. The molding film 400 may cover the side faces of the first semiconductor chip 200 and the side faces of the second semiconductor chip 300. The molding film 400 may cover and wrap around the wire 360.

The molding film 400 may be placed between the first semiconductor chip 200 and the package substrate 100. The molding film 400 may fill the space between the lower bumps 250, between the first semiconductor chip 200 and the package substrate 100.

The molding film 400 may include or be formed of an insulating material. For example, the molding film 400 may include or be a thermosetting resin such as epoxy resin, or a thermoplastic resin such as polyimide. As another example, the molding film 400 may be an insulating polymer material such as an EMC (Epoxy Molding Compound).

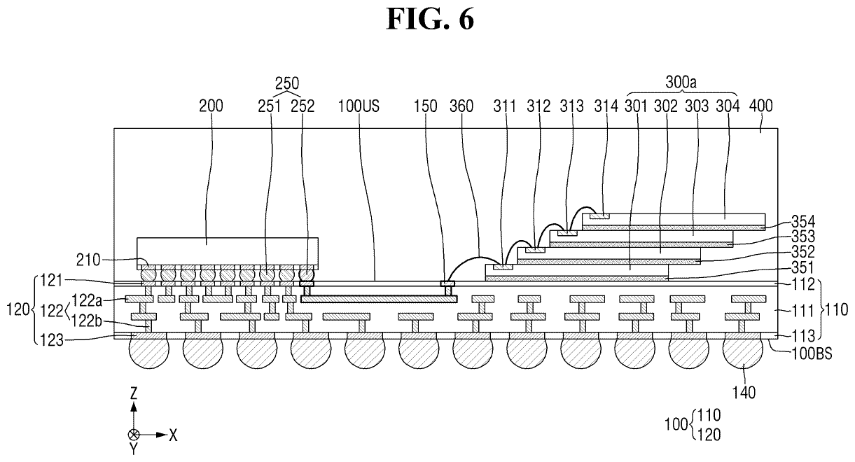

Referring to FIG. 6, a semiconductor package according to some embodiments may include a plurality of memory chips.

The second semiconductor chip stack 300a may include stacked first to fourth memory chips 301 to 304. The first to fourth memory chips 301 to 304 may be stacked stepwise. The first to fourth memory chips 301 to 304 may be stacked in a staircase shape that ascends along the first direction X.

The first memory chip 301 may be placed on the package substrate 100. The first memory chip 301 may include a first adhesive layer 351 on its lower face. The first memory chip 301 may include a first pad 311 on its upper face. The first pad 311 may correspond to the first power/ground pad (310 of FIG. 1) described referring to FIGS. 1 to 4. The first pad 311 may be connected to the option pad 150 by the wire 360.

The first pad 311 may be connected to the option pad 150 and the connecting pad (160 of FIG. 1) at the same time. The first pad 311 may be electrically connected to the external connecting terminal 140 through the connecting pad (160 of FIG. 1). The second semiconductor chip stack 300a may receive a power signal or a ground signal through the connecting pad (160 of FIG. 1) to which the first pad 311 of the first memory chip 301 is connected.

The option pad 150 may provide the option bump 252 with the power signal or ground signal provided to the first pad 311 through the connecting pad (160 of FIG. 1). When there is a need to change the options for controlling the operation of the second semiconductor chip stack 300a, the first semiconductor chip 200 may change the option, using the power signal or ground signal received through the option pad 150 and to be provided to the second semiconductor chip stack 300a.

The second memory chip 302 may be placed on the first memory chip 301. The second memory chip 302 may include a second adhesive layer 352 on its lower face. The second memory chip 302 may include a second pad 312 on its upper face. The second pad 312 may correspond to the first power/ground pad (310 of FIG. 1) described referring FIGS. 1 to 4.

A third memory chip 303 may be placed on the second memory chip 302. The third memory chip 303 may include a third adhesive layer 353 on its lower face. The third memory chip 303 may include a third pad 313 on its upper face. The third pad 313 may correspond to the first power/ground pad (310 of FIG. 1) described referring to FIGS. 1 to 4.

A fourth memory chip 304 may be placed on the third memory chip 303. The fourth memory chip 304 may include a fourth adhesive layer 354 on its lower face. The fourth memory chip 304 may include fourth pad 314 on its upper face. The fourth pad 314 may correspond to the first power/ground pad (310 of FIG. 1) described referring to FIGS. 1 to 4.

Although FIG. 6 shows that the second pad 312 of the second memory chip 302 is connected to the first pad 311 of the first memory chip 301 by a wire, embodiments are not limited thereto. For example, the second pad 312 of the second memory chip 302 may be connected to the connecting pad (160 of FIG. 1) placed on the package substrate 100 by the wire.

Although FIG. 6 shows that the third pad 313 of the third memory chip 303 is connected to the second pad 312 of the second memory chip 302 by the wire, embodiments are not limited thereto. For example, the third pad 313 of the third memory chip 303 may be connected to the connecting pad (160 of FIG. 1) placed on the package substrate 100 by the wire. In another example, the third pad 313 of the third memory chip 303 may be connected to the first pad 311 of the first memory chip 301 by the wire.

Although FIG. 6 shows that the fourth pad 314 of the fourth memory chip 304 is connected to the third pad 313 of the third memory chip 303 by the wire, embodiments are not limited thereto. For example, the fourth pad 314 of the fourth memory chip 304 may be connected to the connecting pad (160 of FIG. 1) placed on the package substrate 100 by the wire. As another example, the fourth pad 314 of the fourth memory chip 304 may be connected to the first pad 311 of the first memory chip 301 by the wire. As another example, the fourth pad 314 of the fourth memory chip 304 may be connected to the second pad 312 of the second memory chip 302 by the wire.

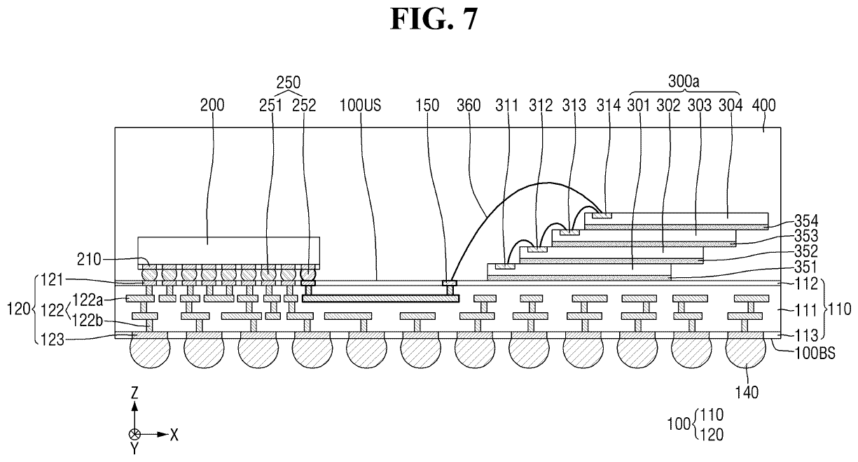

Referring to FIG. 7, the option pad 150 may be connected to the fourth pad 314 of the fourth memory chip 304 by the wire 360. The option pad 150 may provide the option bump 252 with the power signal or ground signal provided to the fourth pad 314. For example, the fourth pad 314 may receive the power signal or ground signal through the first pad 311, the second pad 312, and the third pad 313 connected by the wires. As another example, the fourth pad 314 may receive the power signal or ground signal directly through the connecting pad (160 of FIG. 1).

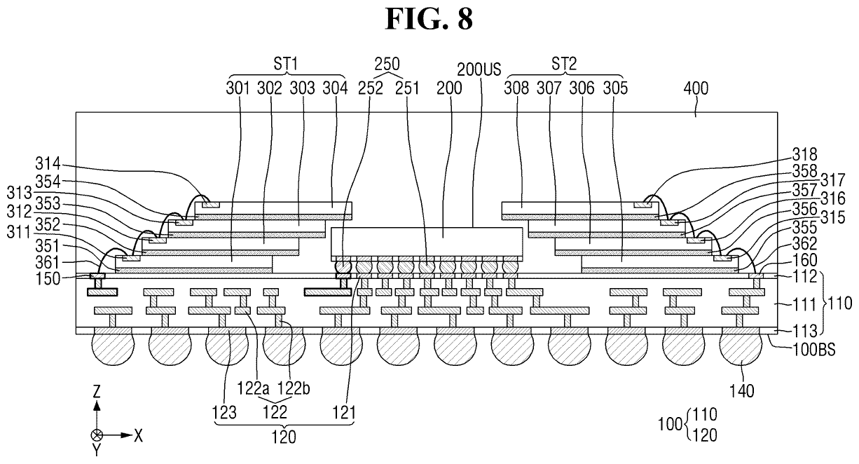

Referring to FIG. 8, the semiconductor package according to some embodiments may include a first chip stack ST1 and a second chip stack ST2. The first chip stack ST1 may include stacked first to fourth memory chips 301 to 304. The first to fourth memory chips 301 to 304 may be stacked in a staircase shape that ascends along the first direction X. The second chip stack ST2 may include stacked fifth to eighth memory chips 305 to 308. The fifth to eighth memory chips 305 to 308 may be stacked in a staircase shape that descends along the first direction X.

The first semiconductor chip 200 may be placed between the first chip stack ST1 and the second chip stack ST2. The first chip stack ST1 and the second chip stack ST2 may be spaced apart in the first direction X with the first semiconductor chip 200 interposed therebetween.

The first through fourth memory chips 301 to 304 may include first to fourth pads 311 to 314. The fifth to eighth memory chips 305 to 308 may include fifth to eighth pads 315 to 318.

The first pad 311 of the first memory chips 301 of the first chip stack ST1 may be connected to the option pad 150 through the first wires 361. The first pad 311 of the first memory chip 301 connected to the option pad 150 may be a power/ground pad. The first pad 311 of the first memory chip 301 connected to the option pad 150 is also connected to the connecting pad 160 by a wire, and may receive the power signal or ground signal from the external connecting terminal 140.

A fifth pad 315 of the fifth memory chip 305 of the second chip stack ST2 may be connected to the connecting pad 160 through the second wire 362.

The second chip stack ST2 may be connected to the external connecting terminal 140 through the fifth pad 315 and the connecting pad 160. The second chip stack ST2 may output the data signal to the external connecting terminal 140 through the fifth pad 315 and the connecting pad 160. The second chip stack ST2 may receive an input signal from the external connecting terminal 140 through the fifth pad 315 and the connecting pad 160.

The second chip stack ST2 may be connected to the first semiconductor chip 200 through the fifth pad 315 and the connecting pad 160. For example, the connecting pad 160 may be connected to the connecting bump 251 of the first semiconductor chip 200 through the wiring structure 120. The second chip stack ST2 may receive the command/address signal from the connecting bump 251 of the first semiconductor chip 200 through the fifth pad 315 and the connecting pad 160.

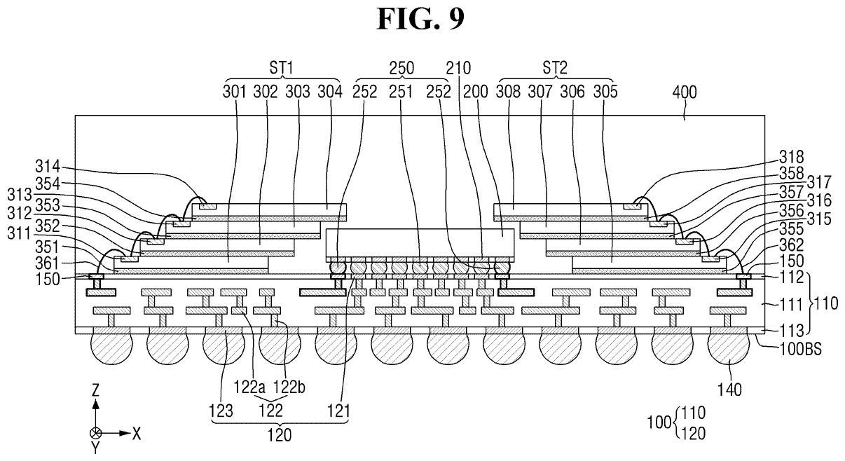

Referring to FIG. 9, the first semiconductor chip 200 may include a plurality of option bumps 252. Some option bumps 252 may be connected to the option pad 150 connected to the first chip stack ST1. Some other option bumps 252 may be connected to the option pad 150 connected to the second chip stack ST2.

A fifth pad 315 of the fifth memory chip 305 of the second chip stack ST2 may be connected to the option pad 150 through the second wire 362. The fifth pad 315 of the fifth memory chip 305 connected to the option pad 150 may be a power/ground pad. The fifth pad 315 of the fifth memory chip 305 connected to the option pad 150 is also connected to the connecting pad 160 by the wire, and may receive the power signal or ground signal from the external connecting terminal 140.

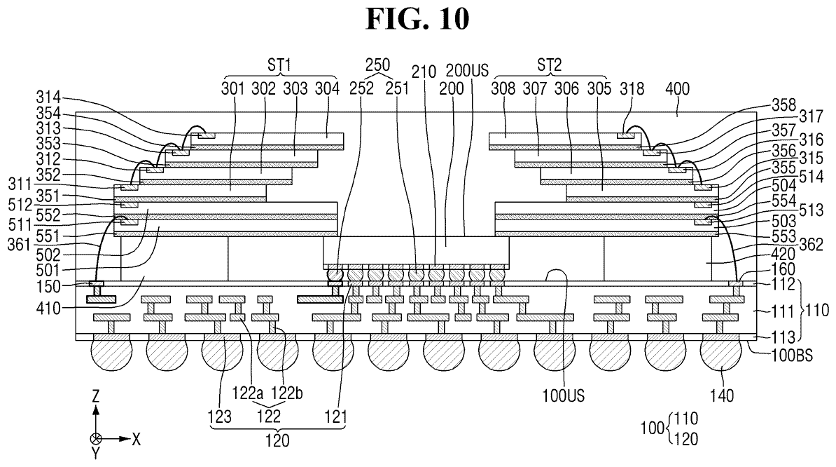

Referring to FIG. 10, a semiconductor package according to some embodiments may include a first dummy chip 410, a second dummy chip 420, a third semiconductor chip 501, a fourth semiconductor chip 502, a fifth semiconductor chip 503, and a sixth semiconductor chip 504.

The first semiconductor chip 200 may be placed between the first dummy chip 410 and the second dummy chip 420. The upper face of the first dummy chip 410 and the upper face of the second dummy chip 420 may be placed on the same plane as the upper face 200US of the first semiconductor chip. However, embodiments are not limited thereto. For example, on the basis of the upper face 100US of the package substrate, the upper face of the first dummy chip 410 and the upper face of the second dummy chip 420 may be placed above the upper face 200US of the first semiconductor chip.

The first dummy chip 410 and the second dummy chip 420 may include silicon, and may be silicon blocks that do not include integrated circuits therein. The first dummy chip 410 and the second dummy chip 420 may be aligned with the first semiconductor chip 200 at the height so that the first chip stack ST1, the second chip stack ST2, the third semiconductor chip 501, the fourth semiconductor chip 502, the fifth semiconductor chip 503, and the sixth semiconductor chip 504 are stacked stably.

The third semiconductor chip 501 and the fourth semiconductor chip 502 may be stacked on the first dummy chip 410 and the first semiconductor chip 200. The third semiconductor chip 501 and the fourth semiconductor chip 502 may be placed below the first chip stack ST1. The fifth semiconductor chip 503 and the sixth semiconductor chip 504 may be stacked on the second dummy chip 420 and the first semiconductor chip 200. The fifth semiconductor chip 503 and the sixth semiconductor chip 504 may be placed below the second chip stack ST2.

The third semiconductor chip 501, the fourth semiconductor chip 502, the fifth semiconductor chip 503, and the sixth semiconductor chip 504 may each include adhesive layers 551 to 554 on their lower faces.

Each of the third semiconductor chip 501, the fourth semiconductor chip 502, the fifth semiconductor chip 503 and the sixth semiconductor chip 504 may be a memory semiconductor chip. The third semiconductor chip 501, the fourth semiconductor chip 502, the fifth semiconductor chip 503 and the sixth semiconductor chip 504 may be, for example, a volatile memory such as a dynamic random access memory (DRAM) or a static random access memory (SRAM). Alternatively, the third semiconductor chip 501, the fourth semiconductor chip 502, the fifth semiconductor chip 503 and the sixth semiconductor chip 504 may include, for example a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

The third semiconductor chip 501, the fourth semiconductor chip 502, the fifth semiconductor chip 503, and the sixth semiconductor chip 504 may include a memory of a type different from the first to fourth memory chips 301 to 304 of the first chip stack ST1 and the fifth to eighth memory chips 305 to 308 of the second chip stack ST2. For example, the first to fourth memory chips 301 to 304 of the first chip stack ST1 and the fifth to eighth memory chips 305 to 308 of the second chip stack ST2 may include a flash memory, and the third semiconductor chip 501, the fourth semiconductor chip 502, the fifth semiconductor chip 503, and the sixth semiconductor chip 504 may include a DRAM.

The third semiconductor chip 501 may include a ninth pad 511. The fourth semiconductor chip 502 may include a tenth pad 512. The ninth pad 511 of the third semiconductor chip 501 may be connected to the option pad 150 through the first wire 361. The ninth pad 511 may be a power/ground pad.

The ninth pad 511 is also connected to the connecting pad 160 by a wire, and may receive the power signal or ground signal from the external connecting terminal 140. The option bump 252 of the first semiconductor chip 200 may receive the power signal or ground signal, which is provided to the ninth pad 511 from the connecting pad 160 and the external connecting terminal 140, from the ninth pad 511 through the option pad 150.

The first semiconductor chip 200 may use the power signal or ground signal provided from the ninth pad 511 through the option pad 150, when there is a need to change an option for controlling the operations of the first chip stack ST1, the second chip stack ST2, the third semiconductor chip 501, the fourth semiconductor chip 502, the fifth semiconductor chip 503, and the sixth semiconductor chip 504.

The fifth semiconductor chip 503 may include an eleventh pad 513. The sixth semiconductor chip 504 may include a twelfth pad 514. The eleventh pad 513 of the fifth semiconductor chip 503 may be connected to the connecting pad 160 through the second wire 362.

For example, the fifth semiconductor chip 503 may be connected to the external connecting terminal 140 through the eleventh pad 513 and the connecting pad 160 connected by the second wire 362. The fifth semiconductor chip 503 may receive the input signal from the external connecting terminal 140 through the eleventh pad 513 and the connecting pad 160. In addition, the fifth semiconductor chip 503 may output the data signal to the external connecting terminal 140 through the eleventh pad 513 and the connecting pad 160. In such a case, the eleventh pad 513 may be a signal pad rather than a power/ground pad.

As another example, the fifth semiconductor chip 503 may receive the power/ground signal from the external connecting terminal 140 through the eleventh pad 513 and the connecting pad 160. In such a case, the eleventh pad 513 may be a power/ground pad rather than the signal pad. However, since the connecting pad 160 is not connected to the option bump 252, it may not provide the first semiconductor chip 200 with the power signal or ground signal received through the external connecting terminal 140.

As still another example, the fifth semiconductor chip 503 may be connected to the first semiconductor chip 200 through the eleventh pad 513 and the connecting pad 160 connected by the second wire 362. The fifth semiconductor chip 503 may receive the command/address signal from the first semiconductor chip 200 through the eleventh pad 513 and the connecting pad 160. In such a case, the eleventh pad 513 may be a signal pad rather than a power/ground pad.

Although FIG. 10 shows that the widths of the third semiconductor chip 501, the fourth semiconductor chip 502, the fifth semiconductor chip 503, and the sixth semiconductor chip 504 are the same, and the side faces thereof are placed on the same plane, the embodiments are not limited thereto. For example, the third semiconductor chip 501 and the fourth semiconductor chip 502 may be stacked stepwise, and the fifth semiconductor chip 503 and the sixth semiconductor chip 504 may be stacked stepwise.

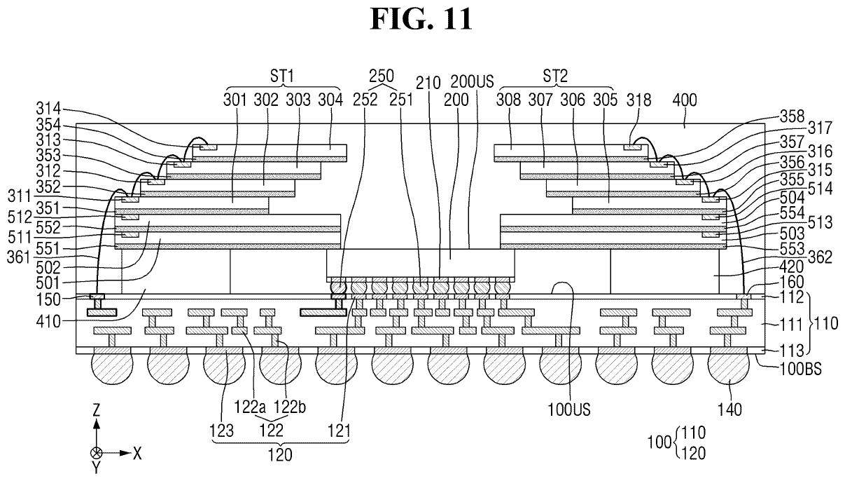

Referring to FIG. 11, the option pad 150 may be connected to the first pad 311 of the first memory chip 301 of the first chip stack ST1 by the first wire 361. The connecting pad 160 may be connected to the fifth pad 315 of the fifth memory chip 305 of the second chip stack ST2 by the second wire 362.

The option pad 150 may be connected to the option bump 252. The option pad 150 may not be connected to the external connecting terminal 140 directly through the wiring structure 120.

The first pad 311 may be connected to the connecting pad 160 in addition to the option pad 150 by the wire, and receive the power signal or ground signal from the external connecting terminal 140. The option bump 252 may receive the power signal or ground signal, which is provided to the first pad 311 from the connecting pad 160 and the external connecting terminal 140, from the first pad 311 through the option pad 150.

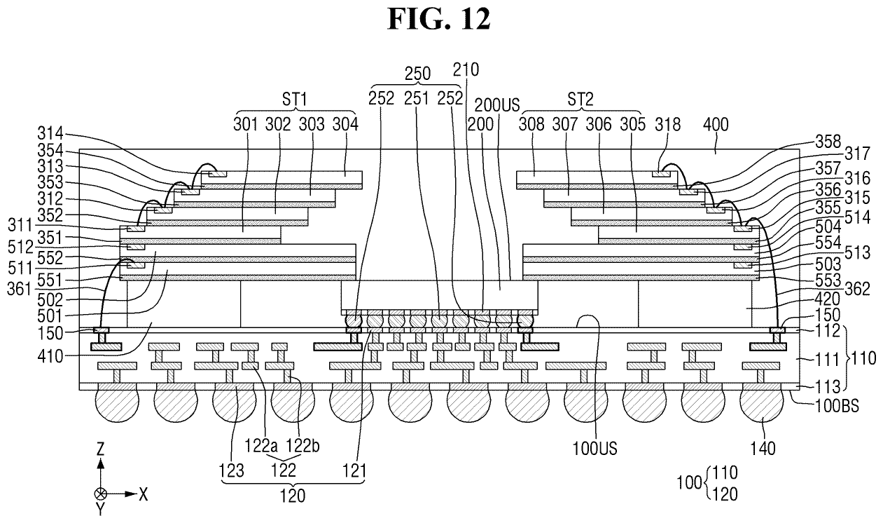

Referring to FIG. 12, the option pad 150 may be connected to the ninth pad 511 of the third semiconductor chip 501 by the first wire 361. The option pad 150 connected to the ninth pad 511 by the first wire 361 may also be connected to the connecting pad (160 of FIG. 1) by the wire. Also, the option pad 150 may be connected to the fifth pad 315 of the fifth memory chip 305 of the second chip stack ST2 by the second wire 362. The option pad 150 connected to the fifth pad 315 by the second wire 362 may also be connected to the connecting pad (160 of FIG. 1) by the wire.

The plurality of option bump 252 may be connected to the option pad 150 connected to the ninth pad 511 of the third semiconductor chip 501 by the first wire 361, and the option pad 150 connected to the fifth pad 315 of the fifth memory chip 305 of the second chip stack ST2 by the second wire 362.

The option bump 252 may receive the power/ground signal of the third semiconductor chip 501 provided to the ninth pad 511 from the external connecting terminal 140 through the connecting pad (160 of FIG. 1), and the power/ground signal of the fifth memory chip 305 provided to the fifth pad 315 from the external connecting terminal 140 through the connecting pad (160 of FIG. 1), through the option pad 150.

Although the embodiments of the present invention have been described above with reference to the accompanying drawings, the present invention is not limited to the above embodiments, and may be fabricated in various forms. Those skilled in the art will appreciate that the present invention may be embodied in other specific forms without changing the technical spirit or essential features of the present invention. Accordingly, the above-described embodiments should be understood in all respects as illustrative and not restrictive.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes. Components described as directly electrically and physically connected are both electrically and physically connected without other components therebetween at a point of contact.

What is claimed is:

1. A semiconductor package comprising:
a package substrate including a wiring structure;
a plurality of external connecting terminals below the package substrate;
a first semiconductor chip flip-chip bonded on and is above the package substrate;
a second semiconductor chip above the package substrate and horizontally spaced apart from the first semiconductor chip, and wire-bonded on the package substrate;
a first power/ground pad on an upper face of the second semiconductor chip;
an option pad on the package substrate and connected to the first power/ground pad by a wire;
an option bump below the first semiconductor chip and connected to the option pad through the wiring structure; and
a connecting bump below the first semiconductor chip and connected to a first external connecting terminal of the plurality of external connecting terminals,
wherein the option bump is not electrically connected to any external connecting terminal of the plurality of external connecting terminals through only the wiring structure.

2. The semiconductor package of claim 1, further comprising:
a first connecting pad which is spaced apart from the option pad on the package substrate, and is connected to the first power/ground pad by a wire.

3. The semiconductor package of claim 2,
wherein the first connecting pad is electrically connected to a second external connecting terminal of the plurality of external connecting terminals through the wiring structure, and
the first connecting pad is not electrically connected to the option bump and the connecting bump through only the wiring structure.

4. The semiconductor package of claim 2, further comprising:
a second power/ground pad on the upper face of the second semiconductor chip, and spaced apart from the first power/ground pad; and
a second connecting pad on the package substrate and spaced apart from the option pad and the first connecting pad, and connected to the second power/ground pad,
wherein the second power/ground pad is not electrically connected to the option pad.

5. The semiconductor package of claim 1,
wherein the second semiconductor chip is a memory chip, and the first semiconductor chip is a controller for controlling the memory chip.

6. The semiconductor package of claim 1, further comprising:
a molding film which covers the first semiconductor chip and the second semiconductor chip on the package substrate.

7. The semiconductor package of claim 1, further comprising:
an adhesive layer placed between the second semiconductor chip and the package substrate.

8. The semiconductor package of claim 1,
wherein a width of the first semiconductor chip in a first direction is smaller than a width of the second semiconductor chip in the first direction.

9. The semiconductor package of claim 1,
wherein the first power/ground pad is configured to receive a power signal or a ground signal of the second semiconductor chip.

10. The semiconductor package of claim 1, further comprising:
a signal pad on the upper face of the second semiconductor chip, and spaced apart from the first power/ground pad.

11. The semiconductor package of claim 10,
wherein the signal pad is not electrically connected to the option pad.

12. The semiconductor package of claim 10,
wherein the signal pad is configured to receive an input/output signal of the second semiconductor chip.

13. A semiconductor package comprising:
a package substrate;
a wiring structure in the package substrate that includes all wiring components that connect between a top of the package substrate and a bottom of the package substrate;
a plurality of external connecting terminals below the package substrate;
a first semiconductor chip flip-chip bonded on and is above the package substrate;
a second semiconductor chip above the package substrate and horizontally spaced apart from the first semiconductor chip, and wire-bonded on the package substrate;
a first pad on an upper face of the second semiconductor chip;
a second pad on the package substrate, and connected to the first pad by a wire;
a first connecting pad spaced apart from the second pad on the package substrate, and connected to the first pad by a wire;
an first bump below the first semiconductor chip on the package substrate, and electrically connected to and contacting the second pad; and
a second bump spaced apart from the first bump below the first semiconductor chip, and electrically connected to a first external connecting terminal of the plurality of external connecting terminals directly through the wiring structure,
wherein the first bump is not electrically connected to any external connecting terminal of the plurality of external connecting terminals directly through the wiring structure, and
wherein the first connecting pad is electrically connected to a second external connecting terminal.

14. The semiconductor package of claim 13,
wherein the first bump is electrically connected to the first external connecting terminal of the plurality of external connecting terminals, but is not electrically connected to the first external connecting terminal directly through the wiring structure.

15. The semiconductor package of claim 13, further comprising:
a third semiconductor chip stacked on the second semiconductor chip, and connected to the second semiconductor chip by a wire.

16. The semiconductor package of claim 15,
wherein the second semiconductor chip and the third semiconductor chip include a memory of the same kind.

17. The semiconductor package of claim 13,
wherein the second bump is a connecting bump, and first bump is an option bump, the wire is a bonding wire, and the second bump and the first bump have the same size.

18. The semiconductor package of claim 13,
wherein the second semiconductor chip is a memory chip, and the first semiconductor chip is a controller for controlling the memory chip.

19. The semiconductor package of claim 13, wherein the first pad is a power/ground pad, the second pad is an option pad, the first bump is an option bump, and the second bump is a connecting bump, and further comprising:
a signal pad placed on the upper face of the second semiconductor chip, and spaced apart from the power/ground pad; and
a second connecting pad spaced apart from the option pad and the first connecting pad on the package substrate, and connected to the signal pad by a wire,
wherein the second connecting pad is not electrically connected to the option bump.

20. A semiconductor package comprising:
a package substrate including a wiring structure;
an external connecting terminal below the package substrate;
a first semiconductor chip on and above the package substrate;
a second semiconductor chip stack spaced apart from the first semiconductor chip on the package substrate and above the package substrate, and including a plurality of stacked memory chips;
a first power/ground pad on an upper face of the second semiconductor chip stack;
a signal pad on an upper face of the second semiconductor chip stack, and spaced apart from the first power/ground pad;
a second power/ground pad on the upper face of the second semiconductor chip stack, and spaced apart from the first power/ground pad and the signal pad;
an option pad on the package substrate, and connected to the first power/ground pad by a wire;
a first connecting pad spaced apart from the option pad on the package substrate, and connected to the first power/ground pad by the wire;
a second connecting pad spaced from the option pad and the first connecting pad on the package substrate, and connected to the second power/ground pad;
a third connecting pad spaced apart from the option pad, the first connecting pad, and the second connecting pad on the package substrate, and connected to the signal pad;
an option bump below the first semiconductor chip on the package substrate, and electrically connected to the option pad through the wiring structure;
a connecting bump spaced apart from the option bump below the first semiconductor chip, and electrically connected to the external connecting terminal; and
a molding film which covers the first semiconductor chip and the second semiconductor chip stack on the package substrate,
wherein the first semiconductor chip includes a controller that controls the plurality of stacked memory chips,
the option bump is not electrically connected to the external connecting terminal directly through the wiring structure,
the option pad is not electrically connected to the external connecting terminal directly through the wiring structure,
the first connecting pad, the second connecting pad, and the third connecting pad are electrically connected to the external connecting terminal, and
the second connecting pad and the third connecting pad are not electrically connected to the option bump.
